(19) United States
(12) Patent Application Publication
(10) Pub. No.: US 2025/0126886 A1
(43) Pub. Date: Apr. 17, 2025

(54) SEMICONDUCTOR DEVICE INCLUDING TWO-DIMENSIONAL SEMICONDUCTOR MATERIAL

(71) Applicant: Samsung Electronics Co., Ltd., Suwon-si (KR)

(72) Inventors: Kyung-Eun BYUN, Suwon-si (KR); Minsu SEOL, Suwon-si (KR); Junyoung KWON, Suwon-si (KR); Huije RYU, Suwon-si (KR)

(73) Assignee: Samsung Electronics Co., Ltd., Suwon-si (KR)

(21) Appl. No.: 18/917,227

(22) Filed: Oct. 16, 2024

(30) Foreign Application Priority Data
Oct. 17, 2023 (KR) 10-2023-0138923

(51) Int. Cl. H01L 27/092; H01L 29/24; H01L 29/76; H01L 29/786

(52) U.S. Cl. CPC H10D 84/85; H10D 30/6728; H10D 30/6757; H10D 48/362; H10D 62/80

(57) ABSTRACT

Provided is a semiconductor device including a two-dimensional (2D) material. The semiconductor device may include a first channel including a first 2D material layer, a second channel apart from the first channel in a first direction and including a second 2D material layer, a common gate electrode between the first channel and the second channel, a first electrode and a second electrode apart from each other and respectively in contact with the first channel and the second channel, and a common electrode apart from the first electrode and the second electrode in a second direction intersecting the first direction and in contact with the first channel and the second channel. One of the first channel and the second channel may be an n-type channel and the other one may be a p-type channel.

### CROSS-REFERENCE TO RELATED APPLICATION

This application is based on and claims priority under 35 U.S.C. § 119 to Korean Patent Application No. 10-2023-0138923, filed on Oct. 17, 2023 in the Korean Intellectual Property Office, the disclosure of which is incorporated by reference herein in its entirety.

### BACKGROUND

### 1. Field

The disclosure relates to a semiconductor device including a two-dimensional (2D) semiconductor material.

### 2. Description of Related Art

According to the miniaturization of semiconductor devices for higher integration degree, research on two-dimensional (2D) materials has been conducted. 2D materials refer to crystalline substances in atomic layers and have been studied as a replacement for silicon. In addition, 2D materials may show stable and excellent properties even in a nano-scale thickness, and thus have been widely used as a next-generation material to overcome the performance degradation issues due to the miniaturization of semiconductor devices.

### SUMMARY

Provided is a semiconductor device including a two-dimensional (2D) semiconductor material.

Additional aspects will be set forth in part in the description which follows and, in part, will be apparent from the description, or may be learned by practice of the presented embodiments of the disclosure.

According to an embodiment of the disclosure, a semiconductor device may include a first channel including a first two-dimensional (2D) material layer; a second channel apart from the first channel in a first direction and including a second 2D material layer; a common gate electrode between the first channel and the second channel; a first electrode and a second electrode apart from each other and respectively in contact with the first channel and the second channel; and a common electrode apart from the first electrode and the second electrode in a second direction, the second direction intersecting the first direction, and the common electrode being in contact with the first channel and the second channel. One of the first channel and the second channel may be an n-type channel, and an other of the first channel and the second channel may be a p-type channel.

In some embodiments, in response to a voltage applied to the common gate electrode, a first one of the first channel and the second channel may be configured to selectively enter a current-on state and a second one of the first channel and the second channel is configured to selectively enter a current-off state, and the first one of the first channel and the second channel and the second one of the first channel and the second channel may be different from each other.

In some embodiments, in response to a first voltage applied to the common gate electrode, the n-type channel among the first channel and the second channel may be configured to enter a current-on state and the p-type channel among the first channel and the second channel is configured to enter a current-off state.

In some embodiments, a second voltage is less than the first voltage, and in response to the second voltage applied to the common gate electrode, the n-type channel from among the first channel and the second channel may be configured to enter the current-off state and the p-type channel is configured to enter the current-on state.

In some embodiments, a channel length of the first channel and a channel length of the second channel may be parallel to the second direction.

In some embodiments, the one of the first channel and the second channel may be doped with an n-type dopant, and the other of the first channel and the second channel may be doped with a p-type dopant.

In some embodiments, the semiconductor device may further include a carrier supply layer for supplying a carrier to at least one of the first 2D material layer and the second 2D material layer.

In some embodiments, the semiconductor device may further include a carrier supply layer in contact with the first 2D material layer, wherein the carrier supply layer may be configured to supply electrons to the first 2D material layer.

In some embodiments, the carrier supply layer may include at least one of WO₃, Ca₂N, Sr₂N, Ba₂N, Y₂C, Gd₂C, Tb₂C, Dy₂C, Ho₂C, Mn₂NO₂H₂, Mn₂CO₂H₂, V₂CO₂H₂, Ti₄C₂O₂H₂, Ti₂CO₂H₂, Ti₂NO₂H₂, Ti₄N₃O₂H₂, Y₄N₃F₂, Hf₃C₂F₂, and Zr₃C₂F₂.

In some embodiments, the semiconductor device may include a carrier supply layer in contact with the second 2D material layer and the carrier supply layer may be configured to supply holes to the second 2D material layer.

In some embodiments, the carrier supply layer may include at least one of RuCl₃, NbS₂, MoO₃, Cr₂C₂O₂, V₂CF₂, Y₂CO₂, Hf₃C₂O₂, Y₄C₃O₂, VS₂, Ti₄C₃O₂, Ti₃C₂O₂, Cr₄N₃O₂, V₃C₂O₂, Mn₂NO₂, V₄C₃O₂, Mn₄N₃O₂, and V₂CO₂.

In some embodiments, the first 2D material layer and the second 2D material layer may include a same 2D semiconductor material.

In some embodiments, the 2D semiconductor material may include at least one of Mo, W, Nb, V, Ta, Ti, Zr, Hf, Tc, Re, Cu, Ga, In, Sn, Ge, and Pb, and the 2D semiconductor material may include at least of S, Se, and Te.

In some embodiments, the semiconductor device may further include a gate insulating layer. The gate insulating layer may be between the first channel and the common gate electrode and the gate insulating layer may be between the second channel and the common gate electrode.

In some embodiments, the semiconductor device may further include an insulator between the first electrode and the second electrode. The insulator may include at least one of a silicon oxide, a silicon nitride, a silicon carbide, and a hexagonal boron nitride (h-BN).

In some embodiments, the common electrode may overlap in the second direction with a part of the first electrode, a part of the second electrode, a part of the first channel, a part of the second channel, and a part of the common gate electrode.

In some embodiments, the common gate electrode and the gate insulating layer may completely surround or partially surround a lateral surface of the first channel and a lateral surface of the second channel.

In some embodiments, the first electrode and the second electrode may be a source electrode, and the common electrode may be a drain electrode.

In some embodiments, a thickness of the first 2D material layer and a thickness of the second 2D material layer may be 3 nm or less.

In some embodiments, the first electrode, the second electrode, and the common electrode may be arranged on a same plane.

According to an embodiment of the disclosure, an electronic apparatus may include the semiconductor device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram of a semiconductor device according to an embodiment;

FIG. 2 is a cross-sectional view of the semiconductor device taken along a line A-A′ in FIG. 1;

FIG. 3 is a plan view of a semiconductor device according to an embodiment;

FIG. 4 is a cross-section view of a semiconductor device according to an embodiment;

FIG. 5 is a cross-section view of a semiconductor device according to an embodiment;

FIG. 6 is a cross-section view of a semiconductor device according to an embodiment;

FIG. 7 is a cross-section view of a semiconductor device according to an embodiment;

FIG. 8 is a cross-section view of a semiconductor device according to an embodiment;

FIG. 9 is a diagram of a semiconductor device according to another embodiment;

FIG. 10 is a plan view of a semiconductor device according to an embodiment;

FIG. 11 is a circuit diagram illustrating circuit configuration of an inverter of FIG. 1;

FIG. 12 is a circuit diagram of a CMOS SRAM device according to an embodiment; and

FIG. 13 is a circuit diagram of a CMOS NAND circuit according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, example embodiments will be described in detail with reference to the accompanying drawings. In the drawings, like reference numerals in the drawings denote like elements, and sizes of components in the drawings may be exaggerated for clarity and convenience of explanation. Meanwhile, embodiments described below are provided only as an example, and thus can be embodied in various forms.

It will be understood that when a component is referred to as being “on” or “over” another component, the component can be directly on, under, on the left of, or on the right of the other component, or can be on, under, on the left of, or on the right of the other component in a non-contact manner. An expression used in the singular encompasses the expression of the plural, unless it has a clearly different meaning in the context. When a portion “includes” an element, another element may be further included, rather than excluding the existence of the other element, unless otherwise described.

The use of the terms “a” and “an” and “the” and similar referents in the context of describing embodiments (especially in the context of the following claims) are to be construed to cover both the singular and the plural. The operations of all methods described herein can be performed in any suitable order unless otherwise indicated herein or otherwise clearly contradicted by context, and embodiments are not limited to the described order of the operations.

Moreover, the terms “part,” “module,” etc. refer to a unit processing at least one function or operation, and may be implemented by a hardware, a software, or a combination thereof.

The connecting lines, or connectors shown in the various figures presented are intended to represent example functional relationships and/or physical or logical couplings between the various elements, and thus it should be noted that many alternative or additional functional relationships, physical connections or logical connections may be present in a practical device.

The use of any and all examples, or example language provided herein, is intended merely to better illuminate technical ideas and does not pose a limitation on the scope of embodiments unless otherwise claimed.

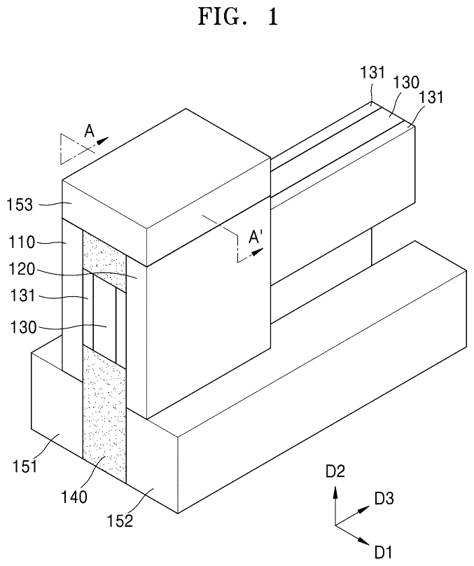

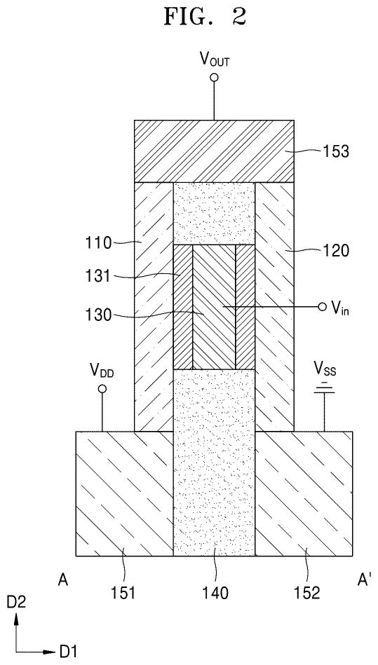

FIG. 1 is a diagram of a semiconductor device according to an embodiment. FIG. 2 is a cross-sectional view of the semiconductor device taken along a line A-A′ in FIG. 1.

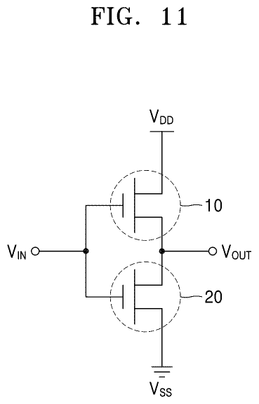

Referring to FIGS. 1 and 2, provided is a semiconductor device 100 including a first transistor 10 and a second transistor 20 connected to each other in a first direction D1 (see first transistor 10 and second transistor 20 in FIG. 11). A first electrode 151, a first channel 110, a common gate electrode 130, and a common electrode 153 may be the first transistor 10, and a second electrode 152, a second channel 120, a common gate electrode 130, and a common electrode 153 may be the second transistor 20.

The first transistor 10 may include the first channel 110 and the first electrode 151 arranged at one end of the first channel 110, the second transistor 20 may include the second channel 120 arranged apart from the first channel 110 in the first direction D1, and the second electrode 152 may be arranged at one end of the second channel 120. The common electrode 153 may be arranged at the other end of each of the first channel 110 and the second channel 120, the common gate electrode 130 and a gate insulating layer 131 may be arranged between the first channel 110 and the second channel 120, and the common gate electrode 130 and the gate insulating layer 131 may be arranged parallel with each other or arranged sequentially in the first direction D1. The first channel 110 and the second channel 120 may have different types from each other, and one of the first channel 110 and the second channel 120 may be an n-type channel, and the other one may be a p-type channel. More specifically, the first channel 110 and the second channel 120 may have different types as they are doped with different dopants from each other, or the first channel 110 and the second channel 120 may have the same 2D material layers but have different types from each other due to carrier supply layers (141a and 141b) to be described later. In addition, the channels may have different types according to the carrier supply layers (141a and 141b) included therein and components thereof, or the channels may include different dopants from each other and may be formed to have different types from each other according to the content of oxygen included in an insulator 140 to be described later. However, the disclosure is not limited thereto.

The first electrode 151 and the second electrode 152 may be arranged below the first channel 110 and the second channel 120, and the first channel 110 and the second channel 120 may extend in a thickness direction of the first electrode 151 and the second electrode 152 and may be arranged on the first electrode 151 and the second electrode 152.

The first and second channels 110 and 120 may include 1 to 10 2D semiconductor material layer(s) (or 1 to 5 2D material layer(s)). That is, the first and second channels 110 and 120 may include a single 2D semiconductor material layer or have a multi-layer structure of up to 10 (or 5) layers in which multiple 2D semiconductor materials are stacked. When few layers (up to 10 layers) of 2D semiconductor materials are stacked, intrinsic properties of 2D semiconductor materials may be maintained.

The first channel 110 may include a first 2D material layer, and the second channel 120 may include a second 2D material layer. The 2D semiconductor material included in the first channel 110 and the second channel 120 refers to a 2D material which has a layered-structure in which constituent atoms are combined in a 2D manner and characteristics of semiconductor. The 2D semiconductor material may have excellent electrical characteristics and even when the 2D semiconductor material has a nano-scale thickness, the mobility thereof may remain high.

TMD is a 2D material having semiconductor characteristics and is a compound of a transition metal and a chalcogen element. The transition metal may include, for example, at least one of Mo, W, Nb, V, Ta, Ti, Zr, Hf, Co, Tc, and Re, and the chalcogen element may include, for example, at least one of S, Se, and Te. The TMD may include, for example, MoS₂, MoSe₂, MoTe₂, WS₂, WSe₂, WTe₂, ZrS₂, ZrSe₂, HfS₂, HfSe₂, NbSe₂, ReSe₂, etc. However, the disclosure is not limited thereto.

The first channel 110 may be a p-type semiconductor, and the second channel 120 may be an n-type semiconductor. In this case, a first metal chalcogenide-based material of the first channel 110 and a second metal chalcogenide-based material of the second channel 120 may include different metallic elements from each other. The first metal chalcogenide-based material of the first channel 110 and the second metal chalcogenide-based material of the second channel 120 may include the same chalcogen element. The first channel 110 may include a first metallic element and a first chalcogen element, and the second channel 120 may include a second metallic element and a second chalcogen element. The first metallic element and the second metallic element may be different from each other, and the first chalcogen element and the second chalcogen element may be identical to each other. When a metallic element is changed in a metal chalcogenide material, the conductivity type (p or n) may be changed as well. Accordingly, when the first channel 110 is a p-type, and the second channel 120 is an n-type, metallic elements thereof may be different from each other. However, in some metallic elements, the conductivity type (p or n) may be changed according to a chalcogen element combined therewith. Therefore, in some cases, the first metallic element and the second metallic element may be identical to each other, and the first chalcogen element and the second chalcogen element may be different from each other. However, the first channel 110 may not be necessarily a p-type semiconductor, and the second channel 120 may not be necessarily an n-type semiconductor.

The first channel 110 may be a metal chalcogenide-based material having p-type semiconductor characteristics and may include at least one of WS₂, ZrS₂, ZrSe₂, HfS₂, HfSe₂, and NbSe₂. The second channel 120 may be a metal chalcogenide-based material having n-type semiconductor characteristics and may include at least one of MoS₂, MoSe₂, MoTe₂, WSe₂, and WTe₂. For example, the first channel 110 may include WS₂ having p-type semiconductor characteristics, and the second channel 120 may include MoS₂ having n-type semiconductor characteristics. The first channel 110 and the second channel 120 may include one of an n-type semiconductor and a p-type semiconductor, and when one of the first channel 110 and the second channel 120 has an n-type semiconductor, the other one may have a p-type semiconductor. The first channel 110 may not necessarily be a p-type semiconductor, and the second channel 120 may not necessarily be an n-type semiconductor.

At least one of the first and second channels 110 and 120 may be doped with a p-type dopant or an n-type dopant. When the first channel 110 is a p-type semiconductor, the first channel 110 may be doped with a p-type dopant, and in some cases, the first channel 110 may be doped with an n-type dopant. Similarly, when the second channel 120 is an n-type semiconductor, the second channel 120 may be doped with an n-type semiconductor or a p-type dopant. For example, when the first channel 110 is WS₂ (p-type), the first channel 110 may be doped with AuCl₃, which is a p-type dopant or doped with K, which is an n-type dopant. That is, the channels may be doped with a dopant of the same or opposite type. When the channel is doped with a dopant of the opposite type, the semiconductor type of the material may be changed.

In addition, each of the first and second channels 110 and 120 may have a single-layer structure (2D plane structure) or a structure in which the single-layer structures (2D plane structures) are repeatedly stacked. When the single-layer structures are repeatedly stacked, the characteristics of the 2D material may be maintained. Electron-structurally, 2D materials may be defined as materials of which density of state (DOS) complies with quantum well behaviors. As the DOS of a material in which a plurality of 2D unit material layers are stacked (100 layers or less) may comply with the quantum well behaviors, in this perspective, the stacked structure of single-layer structures (2D plane structures) may also be referred to as a “2D material.”

The first channel 110 and the second channel 120 may be formed to intersect the first direction D1 or extend in a second direction D2 perpendicular to the first direction D1. The second direction D2 may be a direction perpendicular to a surface of a substrate (not shown). That is, the longitudinal direction of the first channel 110 and the second channel 120 may be parallel with the second direction D2, and the latitudinal direction of the first channel 110 and the second channel 120 may be parallel with the first direction D1.

The first channel 110 and the second channel 120 may respectively have the first electrode 151 and the second electrode 152 connected to one end thereof, and the common electrode 153 may be connected to the other ends of both of the first channel 110 and the second channel 120. The first electrode 151, the second electrode 152, and the common electrode 153 may each be arranged in the latitudinal direction, not in the longitudinal direction of the first channel 110 and the second channel 120.

The first channel 110, the second channel 120, and the common gate electrode 130 may be arranged in the first direction D1, and when the semiconductor device 100 is seen from the first direction D1, the first channel 110, the second channel 120, and the common gate electrode 130 may overlap each other in the first direction D1. That is, the first transistor and the second transistor may overlap each other in the first direction D1. In addition, the first electrode 151, the second electrode 152, and the common electrode 153 may be arranged in the second direction D2, and when the semiconductor device 100 is seen from the second direction D2, the first electrode 151, the second electrode 152, and the common electrode 153 may overlap each other in the second direction D2. That is, the first transistor and the second transistor may overlap each other in the second direction D2. Due to the first transistor and the second transistor which overlap each other in the first direction D1 and the second direction D2, empty spaces of the semiconductor device 100 may be reduced, and the integration degree may increase.

The first electrode 151 may be arranged on the first channel 110, and the second electrode 152 may be arranged on the second channel 120. The common electrode 153 may be arranged on the first and second channels 110 and 120. The common electrode 153 may be in contact with the first and second channels 110 and 120. The first electrode 151 may be a source electrode of the first transistor (hereinafter, the “first source electrode”). The common electrode 153 may include a drain electrode of the first transistor (hereinafter, the “first drain electrode”). That is, the common electrode 153 may function as a first drain electrode of the first transistor. The common electrode 153 may include a drain electrode of the second transistor (hereinafter, the “second drain electrode”). That is, the common electrode 153 may function as a second drain electrode of the second transistor. The second electrode 152 may be a source electrode of the second transistor (hereinafter, the “second source electrode”). The first and second electrodes 151 and 152 and the common electrode 153 may include various metals or metallic compounds. In addition, the first and second electrodes 151 and 152 and the common electrode 153 may include a conductive 2D material or a bulk material which is not a 2D material.

The common gate electrode 130 may be arranged apart from the first and second channels 110 and 120. The gate insulating layer 131 may be arranged between the common gate electrode 130 and the first and second channels 110 and 120. The gate insulating layer 131 may be arranged on the common gate electrode 130, and the first and second channels 110 and 120 arranged apart from each other may be provided on the gate insulating layer 131.

The common gate electrode 130 may be a kind of conductor substrate. The common gate electrode 130 may include a conductive 2D material or a material which is not a 2D material (hereinafter, the “bulk material”). For example, the common gate electrode 130 may include a metal such as Cu, Ni, Fe, Co, Pt, Ru, etc. or include graphene. Or, the common gate electrode 130 may include a doped silicon (Si). The gate insulating layer 131 may include an insulating 2D material or a bulk material which is not a 2D material. The gate insulating layer 131 may include at least one of a high-k oxide, a silicon oxide, and a 2D insulating material. The gate insulating layer 131 may include, for example, an aluminum oxide, a hafnium oxide, a zirconium oxide, a lanthanum oxide, etc. as a high-k oxide. The gate insulating layer 131 may include, for example, h-BN as a 2D insulating material. However, the disclosure is not limited thereto. The gate insulating layer 131 may include an insulating 2D material such as h-BN. However, in some cases, the gate insulating layer 131 may include an insulating material such as SiO₂, SiNₓ, AlN, Al₂O₃, HfO₂, ZrO₂, etc. The common gate electrode 130 and the gate insulating layer 131 may be combined to form a substrate. Or, a separate substrate (not shown) may be provided under the common gate electrode 130.

More specifically, the substrate (not shown) may be arranged on one side of the first transistor and the second transistor. The substrate (not shown) may include a channel. A substrate 101 may include various materials such as a semiconductor material, an insulating material, a metal material, etc. When the first channel 110 and the second channel 120 which include a 2D semiconductor material layer are formed by depositing a 2D semiconductor material on the substrate 101, the substrate 101 may be a substrate for growth of 2D semiconductor material.

The insulator 140 may be arranged between the first and second channels 110 and 120. The insulator 140 may include a silicon oxide, a silicon nitride, a silicon carbide, and a 2D material. In this case, the insulator 140 may include, for example, h-BN. However, the material of the insulator 140 is not limited to h-BN and may vary. The material of the insulator 140 may not be a 2D material.

The insulator 140 may include a low-k material. The permittivity of the insulator 140 may be 3 to 5. However, the disclosure is not limited thereto.

A part of the first channel 110, the common gate electrode 130, the gate insulating layer 131, the first electrode 151, and the common electrode 153 may constitute the first transistor. The first transistor may be a p-type transistor. A part of the second channel 120, the common gate electrode 130, the gate insulating layer 131, the second electrode 152, and the common electrode 153 may constitute the second transistor. The second transistor 20 may be an n-type transistor. According to a voltage applied to the common gate electrode 130, an electrical barrier of the first channel 110 may be adjusted, and the on/off state of the first transistor may be controlled. Similarly, according to a voltage applied to the common gate electrode 130, an electrical barrier of the second channel 120 may be adjusted, and the on/off state of the second transistor may be controlled. When the thickness of the first and second channels 110 and 120 is thin (for example, 5 nm or less), the first and second transistors may be a tunneling barrier device, and when the thickness of the first and second channels 110 and 120 is relatively thick (for example, scores of nanometers), the first and second transistor may be a Schottky barrier device. In addition, the thickness of the first 2D material layer and the second 2D material layer may be 3 nm or less, but the disclosure is not limited thereto.

Based on a voltage applied to the common gate electrode 130, the semiconductor device 100 according to an embodiment may function as an inverter in which one of the first channel 110 and the second channel 120 may selectively enter the current-on state, and the other one may enter the current-off state. More specifically, in the semiconductor device 100 according to an embodiment, when the first voltage is applied to the common gate electrode 130, an n-type channel from among the first channel 110 and the second channel 120 may enter the current-on state, and a p-type channel may enter the current-off state, and when a second voltage, which is less than the first voltage, is applied to the common gate electrode 130, an n-type channel from among the first channel 110 and the second channel 120 may enter the current-off state, and a p-type channel may enter the current-on state.

The semiconductor device 100 according to an embodiment may be a complementary metal oxide semiconductor (CMOS) inverter. The CMOS inverter may have a structure in which gates of the NMOSFET and the PMOSFET are connected to receive an input voltage Vin, and drains of the NMOSFET and the PMOSFET are connected to release an output voltage Vout.

The first electrode 151 may be connected to a power terminal VDD. The second electrode 152 may be connected to a ground terminal VSS. In other words, the second electrode 152 may be grounded. The common gate electrode 130 may be connected to an input terminal VIN. The common electrode 153 may be connected to an output terminal VOUT. According to an input signal (voltage) applied to the common gate electrode 130 through the input terminal VIN, the on/off state of a first transistor TR10 and a second transistor TR20 may be controlled, and signals output through the output terminal VOUT may be changed. For example, when a signal corresponding to “1” is input to the input terminal VIN, a signal corresponding to “0” may be output through the output terminal VOUT. When a signal corresponding to “0” is input to the input terminal VIN, a signal corresponding to “1” may be output through the output terminal VOUT. Accordingly, the device of FIG. 1 may function as an inverter.

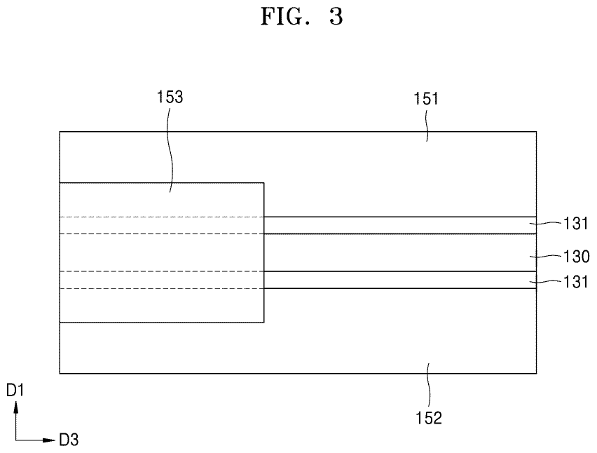

FIG. 3 is a plan view of a semiconductor device according to an embodiment.

FIG. 3 illustrates a top-view of the semiconductor device of FIG. 1, e.g., a view of the semiconductor device seen from the opposite direction of the second direction D2. As described in relation to FIG. 1, the common electrode 153, the first electrode 151, and the second electrode 152 may overlap each other, and the common gate electrode 130 and the gate insulating layer 131 may be formed to extend in a third direction D3 perpendicular to both of the first direction D1 and the second direction D2.

The first electrode 151, the second electrode 152, and the common electrode 153 may be arranged in the second direction D2, and when the semiconductor device 100 is seen from the second direction D2, the first electrode 151, the second electrode 152, and the common electrode 153 may overlap each other in the second direction D2. That is, the first transistor and the second transistor may overlap each other in the second direction D2. Due to the first transistor and the second transistor which overlap each other in the first direction D1 and the second direction D2, empty spaces of the semiconductor device 100 may be reduced, and the integration degree may increase.

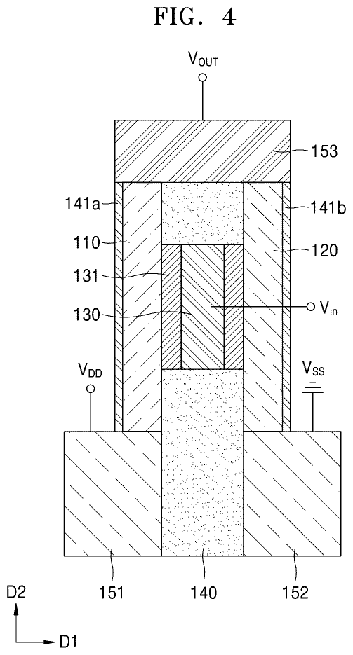

FIG. 4 is a cross-section view of a semiconductor device according to an embodiment.

Referring to FIG. 4, an interface layer formed on one side of the first channel 110 and the second channel 120 of the semiconductor device of FIG. 2 may be further provided. The interface layer may include a carrier supply layer supplying a carrier to the channels of the semiconductor device. More specifically, at least one of the first channel 110 and the second channel 120 may further include a carrier supply layer supplying a carrier to the first 2D material layer and the second 2D material layer. The carrier supply layer may be arranged on one side of the first channel 110 and the second channel 120 including a 2D material. The carrier supply layer may supply a carrier, for example, an electrode or a hole to the first and second 2D material layers. In addition, the carrier supply layer may include an insulating 2D material. As the carrier supply layer includes a 2D material, the volume of the semiconductor device 100 may be reduced. For example, the thickness of the carrier supply layer may be less than the thickness of the first and second 2D material layers. As the carrier supply layer includes a 2D material and thus is stable, diffusion of the material of the carrier supply layer into the 2D material layer having semiconductor characteristics may be limited and/or prevented.

The first channel 110 may include a first carrier supply layer 141a in contact with the first 2D material layer and supplying electrons to the first 2D material layer. The first carrier supply layer 141a may include at least one of WO₃, Ca₂N, Sr₂N, Ba₂N, Y₂C, Gd₂C, Tb₂C, Dy₂C, Ho₂C, Mn₂NO₂H₂, Mn₂CO₂H₂, V₂CO₂H₂, Ti₄C₂O₂H₂, Ti₂CO₂H₂, Ti₂NO₂H₂, Ti₄N₃O₂H₂, Y₄N₃F₂, Hf₃C₂F₂, and Zr₃C₂F₂; however, the disclosure is not limited thereto. The second channel 120 may include a second carrier supply layer 141b in contact with the second 2D material layer and supplying holes to the second 2D material layer. The second carrier supply layer 141b may include at least one of RuCl₃, NbS₂, MoO₃, Cr₂C₂O₂, V₂CF₂, Y₂CO₂, Hf₃C₂O₂, Y₄C₃O₂, VS₂, Ti₄C₃O₂, Ti₃C₂O₂, Cr₄N₃O₂, V₃C₂O₂, Mn₂NO₂, V₄C₃O₂, Mn₄N₃O₂, and V₂CO₂; however, the disclosure is not limited thereto. In some embodiments, the first carrier supply layer 141a may include at least one of RuCl₃, NbS₂, MoO₃, Cr₂C₂O₂, V₂CF₂, Y₂CO₂, Hf₃C₂O₂, Y₄C₃O₂, VS₂, Ti₄C₃O₂, Ti₃C₂O₂, Cr₄N₃O₂, V₃C₂O₂, Mn₂NO₂, V₄C₃O₂, Mn₄N₃O₂, and V₂CO₂ and the second carrier supply layer 141b may include at least one of WO₃, Ca₂N, Sr₂N, Ba₂N, Y₂C, Gd₂C, Tb₂C, Dy₂C, Ho₂C, Mn₂NO₂H₂, Mn₂CO₂H₂, V₂CO₂H₂, Ti₄C₂O₂H₂, Ti₂CO₂H₂, Ti₂NO₂H₂, Ti₄N₃O₂H₂, Y₄N₃F₂, Hf₃C₂F₂, and Zr₃C₂F₂; however, the disclosure is not limited thereto.

When the first channel 110 and the second channel 120 include the same material, the type of the first channel 110 and the second channel 120 may be determined according to an interface layer provided on one side of the first channel 110 and the second channel 120. The material of the interface layer may include an aluminum oxide; however, the disclosure is not limited thereto. By adjusting the content of oxygen and aluminum of aluminum oxide included in the interface layer, properties of the interface layer may be determined, and the type of the first channel 110 and the second channel 120 may be determined according to the properties of the interface layer. That is, even when the first channel 110 and the second channel 120 include the same material, one of the first channel 110 and the second channel 120 may be an n-type semiconductor, and the other one may be a p-type semiconductor. Other features of the embodiment may be understood may referring to the description provided above in relation to FIGS. 1 and 2.

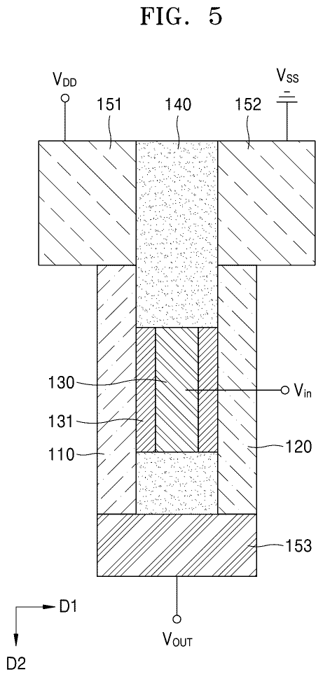

FIG. 5 is a cross-section view of a semiconductor device according to an embodiment.

Referring to FIG. 5, in the semiconductor device 100 including the first transistor and the second transistor connected to each other in the first direction D1, the first transistor may include the first channel 110 and the first electrode 151 arranged at one end of the first channel 110, the second transistor may include the second channel 120 arranged apart from the first channel 110 in the first direction D1, and the second electrode 152 may be arranged at one end of the second channel 120. The common electrode 153 may be arranged at the other end of each of the first channel 110 and the second channel 120, the common gate electrode 130 and a gate insulating layer 131 may be arranged between the first channel 110 and the second channel 120, and the common gate electrode 130 and the gate insulating layer 131 may be arranged parallel with each other or arranged sequentially in the first direction D1.

The first channel 110 and the second channel 120 may have different types from each other, and one of the first channel 110 and the second channel 120 may be an n-type channel, and the other one may be a p-type channel. More specifically, the first channel 110 and the second channel 120 may have different types from each other because of the channels doped with different dopants from each other, or according to the carrier supply layers 141a and 141b when the channels include the same dopant. Also, the first channel 110 and the second channel 120 may have different types according to electrodes in contact with the channels when the channels include the same dopant, or according to the content of oxygen included in the insulator 140 when the channels include different dopants from each other. However, the disclosure is not limited thereto.

More specifically, the first electrode 151 and the second electrode 152 may be arranged on the first channel 110 and the second channel 120, and the first channel 110 and the second channel 120 may extend in the thickness direction of the common electrode 153 and may be arranged under the first electrode 151 and the second electrode 152.

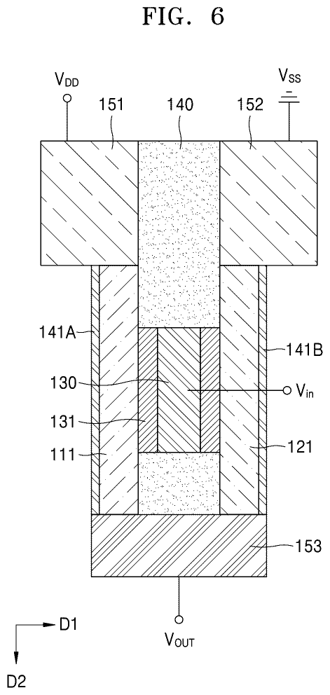

FIG. 6 is a cross-section view of a semiconductor device according to an embodiment.

Referring to FIG. 6, an interface layer formed on one side of a first channel 111 and a second channel 121 of the semiconductor device of FIG. 5 may be further provided. For example, a first interface layer 141A may be formed on one side of the first channel 111 and a second interface layer 141B may be formed on one side of the second channel 121. Even when the first channel 111 and the second channel 121 include the same material, the type of the first channel 111 and the second channel 121 may be determined according to the material of the interface layer. More specifically, the material of the interface layer may include an aluminum oxide; however, the disclosure is not limited thereto. By adjusting the content of oxygen and aluminum of aluminum oxide, properties of the interface layer may be determined, and the type of the first channel 111 and the second channel 121 may be determined according to the properties of the interface layer. That is, even when the first channel 111 and the second channel 121 include the same material, one of the first channel 111 and the second channel 121 may be an n-type semiconductor, and the other one may be a p-type semiconductor. Other features of the embodiment may be understood may referring to the description provided above in relation to FIGS. 1 and 2. The first channel 111 and the second channel 121 may be a same two-dimensional material and may include one of MoS₂, MoSe₂, MoTe₂, WS₂, WSe₂, WTe₂, ZrS₂, ZrSe₂, HfS₂, HfSe₂, NbSe₂, ReSe₂, etc.; however, the disclosure is not limited thereto.

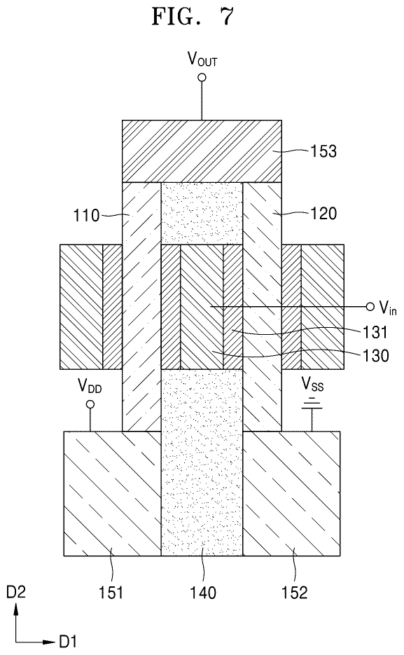

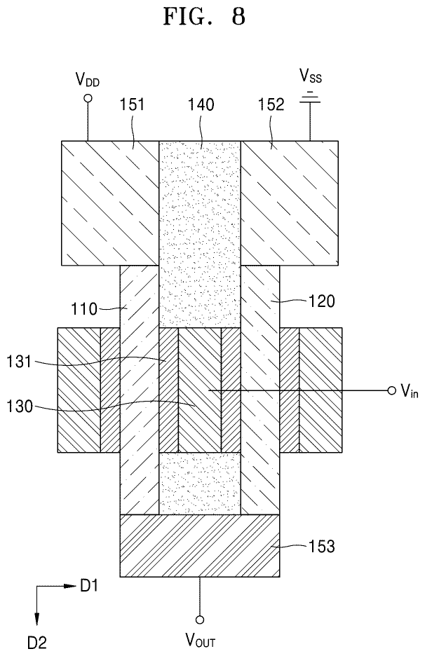

FIG. 7 is a cross-section view of a semiconductor device according to an embodiment. FIG. 8 is a cross-section view of a semiconductor device according to an embodiment.

Referring to FIGS. 7 and 8, in the semiconductor device including the first transistor and the second transistor connected to each other in the first direction D1, the first transistor may include the first channel 110 and the first electrode 151 arranged at one end of the first channel 110, the second transistor may include the second channel 120 arranged apart from the first channel 110 in the first direction D1, and the second electrode 152 may be arranged at one end of the second channel 120. The common electrode 153 may be arranged at the other end of each of the first channel 110 and the second channel 120, the common gate electrode 130 and a gate insulating layer 131 may be arranged between the first channel 110 and the second channel 120, and the common gate electrode 130 and the gate insulating layer 131 may be arranged to partially or completely surround a lateral surface of the first channel 110 and the second channel 120. That is, the common gate electrode 130 and the gate insulating layer 131 may be arranged to completely surround the lateral surface of the first channel 110 and the second channel 120 or surround the half of the circumference of each of the first channel 110 and the second channel 120, thereby forming a fork shape.

The first channel 110 and the second channel 120 may have different types from each other, and one of the first channel 110 and the second channel 120 may be an n-type channel, and the other one may be a p-type channel. More specifically, the first channel 110 and the second channel 120 may have different types from each other because of the channels doped with different dopants from each other, or according to the carrier supply layers 141a and 141b when the channels include the same dopant. Also, the first channel 110 and the second channel 120 may have different types according to electrodes in contact with the channels when the channels include the same dopant, or according to the content of oxygen included in the insulator 140 when the channels include different dopants from each other. However, the disclosure is not limited thereto.

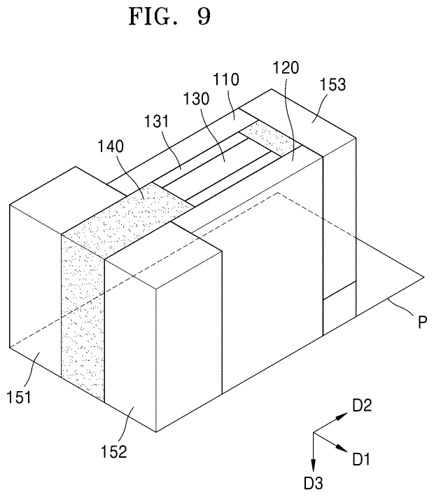

FIG. 9 is a diagram of a semiconductor device according to another embodiment.

Referring to FIG. 9, in the semiconductor device including the first transistor and the second transistor connected to each other in the first direction D1, the first electrode 151, the second electrode 152, and the common electrode 153 may be arranged on the same plane P. The length of the first channel 110 and the second channel 120 may be parallel with the second direction D2.

The first transistor 10 may include the first channel 110 and the first electrode 151 arranged at one end of the first channel 110, the second transistor 20 may include the second channel 120 arranged apart from the first channel 110 in the first direction D1, and the second electrode 152 may be arranged at one end of the second channel 120. The common electrode 153 may be arranged at the other end of each of the first channel 110 and the second channel 120, the common gate electrode 130 and a gate insulating layer 131 may be arranged between the first channel 110 and the second channel 120, and the common gate electrode 130 and the gate insulating layer 131 may be arranged parallel with each other or arranged sequentially in the first direction D1. The first channel 110 and the second channel 120 may have different types from each other, and one of the first channel 110 and the second channel 120 may be an n-type channel, and the other one may be a p-type channel. More specifically, the first channel 110 and the second channel 120 may have different types from each other because of the channels doped with different dopants from each other, or according to the carrier supply layers 141a and 141b when the channels include the same dopant. Also, the first channel 110 and the second channel 120 may have different types according to electrodes in contact with the channels when the channels include the same dopant, or according to the content of oxygen included in the insulator 140 when the channels include different dopants from each other. However, the disclosure is not limited thereto.

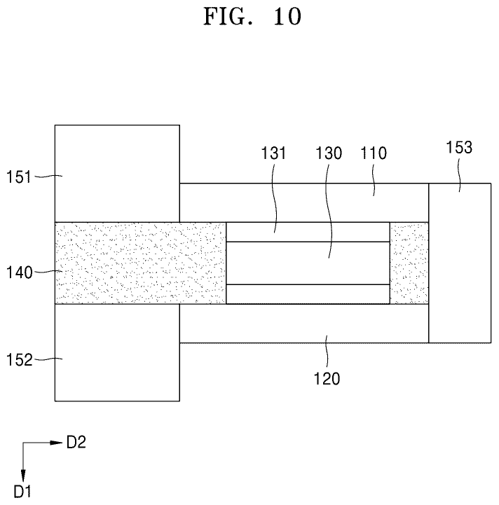

FIG. 10 is a plan view of a semiconductor device according to an embodiment.

FIG. 10 illustrates a top-view of the semiconductor device of FIG. 9, e.g., a view of the semiconductor device seen from the third direction D3. The common electrode 153, the first electrode 151, and the second electrode 152 may overlap each other in the first direction D1, and the common gate electrode 130 and the gate insulating layer 131 may be formed to extend in the second direction D2 perpendicular to both of the first direction D1 and the third direction D3.

The first electrode 151, the second electrode 152, and the common electrode 153 may be arranged in the second direction D2, and when the semiconductor device is seen from the second direction D2, the first electrode 151, the second electrode 152, and the common electrode 153 may overlap each other in the second direction D2. That is, the first transistor and the second transistor may overlap each other in the first direction D1. Due to the first transistor and the second transistor which overlap each other in the first direction D1 and the second direction D2, empty spaces of the semiconductor device may be reduced, and the integration degree may increase.

FIG. 11 is a circuit diagram illustrating circuit configuration of an inverter of FIG. 1.

Referring to FIG. 2, the first transistor 10 and the second transistor 20 may be connected to each other. The first transistor 10 may be a p-type, and the second transistor 20 may be an n-type. The power terminal VDD may be connected to a drain of the first transistor 10. The output terminal VOUT may be connected to a source of the first transistor 10 and a drain of the second transistor 20. The ground terminal VSS may be connected to a source of the second transistor 20. The input terminal VIN may be connected to a gate electrode (common gate electrode) of the first and second transistors 10 and 20. As described above, according to an input signal (voltage) applied to the common gate electrode through the input terminal VIN, the on/off state of the first and second transistors 10 and 20 may be controlled, and signals output through the output terminal VOUT may be changed. The circuit configuration of FIG. 2 may be applied to the structures of FIGS. 3 to 10 as well.

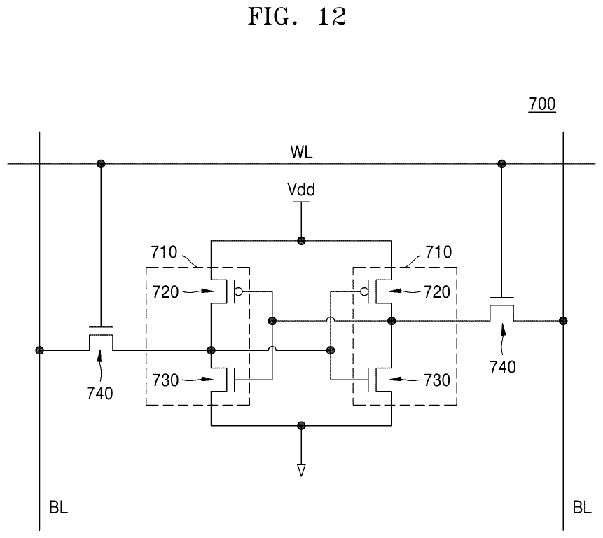

FIG. 12 is a circuit diagram of a CMOS SRAM device 700 according to an embodiment.

Referring to FIG. 12, the CMOS SRAM device 700 may include a pair of driver transistors 710. The pair of driver transistors 710 may each include a PMOS transistor 720 and an NMOS transistor 730 connected between a power terminal Vdd and a ground terminal. The CMOS SRAM device 700 may further include a pair of transmission transistors 740. A source of the transmission transistor 740 may be cross-connected to a common node of the PMOS transistor 720 and the NMOS transistor 730 constituting the driver transistor 710. The power terminal Vdd may be connected to the source of the PMOS transistor 720, and the ground terminal may be connected to the source of the NMOS transistor 730. A word line WL may be connected to the gate of the pair of the transmission transistors 740, and a bit line BL and an inverted bit line may be respectively connected to drains of each of the pair of transmission transistors 740. At least one of the driver transistor 710 and the transmission transistor 740 of the CMOS SRAM device 700 may include one of the semiconductor devices according to the embodiments described in relation to FIGS. 1 to 10 or a semiconductor device embodied according to various combinations of the foregoing embodiments.

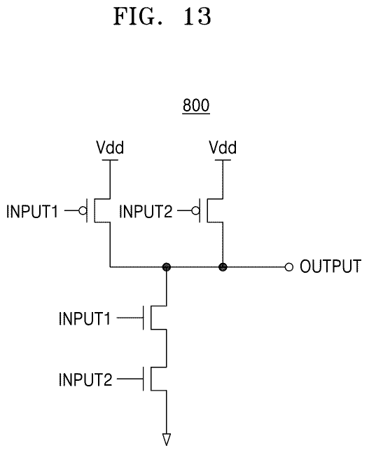

FIG. 13 is a circuit diagram of a CMOS NAND circuit according to an embodiment.

Referring to FIG. 13, a CMOS NAND circuit 800 may include a pair of CMOS transistors to which different input signals are transmitted. The CMOS NAND circuit 800 may include one of the semiconductor devices according to the embodiments described in relation to FIGS. 1 to 10 or a semiconductor device embodied according to various combinations of the foregoing embodiments.

A semiconductor device according to an embodiment may include a first channel arranged perpendicular to a plurality of electrodes, a second channel, first and second electrodes connected to the channels, and a common electrode, and the plurality of electrodes or channels may overlap each other in one of the first direction and the second direction, which may lead to reduced space of semiconductor device and improved integration degree.

Moreover, the semiconductor device according to an embodiment may be an inverter including the first transistor and the second transistor. By using the inverter, various logic devices may be implemented, and in this case, the performance and operational characteristics of the logic devices may be improved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a first channel including a first two-dimensional (2D) material layer;
a second channel apart from the first channel in a first direction and including a second 2D material layer;
a common gate electrode between the first channel and the second channel;
a first electrode and a second electrode apart from each other and respectively in contact with the first channel and the second channel; and
a common electrode apart from the first electrode and the second electrode in a second direction, the second direction intersecting the first direction, and the common electrode being in contact with the first channel and the second channel, wherein
one of the first channel and the second channel is an n-type channel, and
an other of the first channel and the second channel is a p-type channel.

2. The semiconductor device of claim 1, wherein
in response to a voltage applied to the common gate electrode, a first one of the first channel and the second channel is configured to selectively enter a current-on state and a second one of the first channel and the second channel is configured to selectively enter a current-off state, and
the first one of the first channel and the second channel and the second one of the first channel and the second channel are different from each other.

3. The semiconductor device of claim 1, wherein,
in response to a first voltage applied to the common gate electrode, the n-type channel among the first channel and the second channel is configured to enter a current-on state and the p-type channel among the first channel and the second channel is configured to enter a current-off state.

4. The semiconductor device of claim 3, wherein
a second voltage is less than the first voltage,
in response to the second voltage applied to the common gate electrode, the n-type channel from among the first channel and the second channel is configured to enter the current-off state and the p-type channel is configured to enter the current-on state.

5. The semiconductor device of claim 1, wherein a channel length of the first channel and a channel length of the second channel are parallel to the second direction.

6. The semiconductor device of claim 1, wherein
the one of the first channel and the second channel is doped with an n-type dopant, and
the other of the first channel and the second channel is doped with a p-type dopant.

7. The semiconductor device of claim 1, further comprising:
a carrier supply layer for supplying a carrier to at least one of the first 2D material layer and the second 2D material layer.

8. The semiconductor device of claim 1, further comprising:
a carrier supply layer in contact with the first 2D material layer, wherein
the carrier supply layer is configured to supply electrons to the first 2D material layer.

9. The semiconductor device of claim 8, wherein
the carrier supply layer includes at least one of WO₃, Ca₂N, Sr₂N, Ba₂N, Y₂C, Gd₂C, Tb₂C, Dy₂C, Ho₂C, Mn₂NO₂H₂, Mn₂CO₂H₂, V₂CO₂H₂, Ti₄C₂O₂H₂, Ti₂CO₂H₂, Ti₂NO₂H₂, Ti₄N₃O₂H₂, Y₄N₃F₂, Hf₃C₂F₂, and Zr₃C₂F₂.

10. The semiconductor device of claim 1, wherein
a carrier supply layer in contact with the second 2D material layer, wherein
the carrier supply layer is configured to supply holes to the second 2D material layer.

11. The semiconductor device of claim 10, wherein the carrier supply layer includes at least one of RuCl₃, NbS₂, MoO₃, Cr₂C₂O₂, V₂CF₂, Y₂CO₂, Hf₃C₂O₂, Y₄C₃O₂, VS₂, Ti₄C₃O₂, Ti₃C₂O₂, Cr₄N₃O₂, V₃C₂O₂, Mn₂NO₂, V₄C₃O₂, Mn₄N₃O₂, and V₂CO₂.

12. The semiconductor device of claim 1, wherein the first 2D material layer and the second 2D material layer include a same 2D semiconductor material.

13. The semiconductor device of claim 12, wherein
the same 2D semiconductor material includes at least one of Mo, W, Nb, V, Ta, Ti, Zr, Hf, Tc, Re, Cu, Ga, In, Sn, Ge, and Pb, and
the same 2D semiconductor material includes at least one of S, Se, and Te.

14. The semiconductor device of claim 1, further comprising:
a gate insulating layer, wherein
the gate insulating layer is between the first channel and the common gate electrode and the gate insulating layer is between the second channel and the common gate electrode.

15. The semiconductor device of claim 1, further comprising:
an insulator between the first electrode and the second electrode, wherein
the insulator includes at least one of a silicon oxide, a silicon nitride, a silicon carbide, and a hexagonal boron nitride (h-BN).

16. The semiconductor device of claim 1, wherein the common electrode overlaps in the second direction with a part of the first electrode, a part of the second electrode, a part of the first channel, a part of the second channel, and a part of the common gate electrode.

17. The semiconductor device of claim 14, wherein
the common gate electrode and the gate insulating layer completely surround or partially surround a lateral surface of the first channel and a lateral surface of the second channel.

18. The semiconductor device of claim 1, wherein a thickness of the first 2D material layer and a thickness of the second 2D material layer each are 3 nm or less.

19. The semiconductor device of claim 1, wherein the first electrode, the second electrode, and the common electrode are arranged on a same plane.

20. An electronic apparatus comprising: the semiconductor device of claim 1.
